(19) United States
(12) Patent Application Publication
(10) Pub. No.: US 2025/0107123 A1
(43) Pub. Date: Mar. 27, 2025

(54) GA2O3 P-N JUNCTIONS AND METHOD OF MANUFACTURING THE SAME

(71) Applicants: Houqiang Fu, Chandler, AZ (US); Dinusha Herath Mudiyanselage, Mesa, AZ (US); Dawei Wang, Tempe, AZ (US)

(72) Inventors: Houqiang Fu, Chandler, AZ (US); Dinusha Herath Mudiyanselage, Mesa, AZ (US); Dawei Wang, Tempe, AZ (US)

(21) Appl. No.: 18/898,925

(22) Filed: Sep. 27, 2024

Related U.S. Application Data
(60) Provisional application No. 63/585,718, filed on Sep. 27, 2023.

(51) Int. Cl. H01L 29/737; H01L 29/04; H01L 29/24; H01L 29/66

(52) U.S. Cl. CPC H10D 10/821; H10D 62/405; H10D 62/80; H10D 99/00

(57) ABSTRACT

A Ga₂O₃ heterojunction bipolar device includes a first electrode, a second electrode, a β-Ga₂O₃ substrate between the first electrode and the second electrode, and a NiOₓ layer in contact with (2̅01), (001), or (010) plane of the β-Ga₂O₃ substrate. A surface of the β-Ga₂O₃ substrate defines a (2̅01), (001), or (010) plane, and the interface between the NiOₓ layer and the β-Ga₂O₃ substrate is a p-n heterojunction. Fabricating the Ga₂O₃ heterojunction bipolar device includes depositing a first electrode on a surface of a Ga₂O₃ substrate defining a (2̅01), (001), or (010) plane of the β-Ga₂O₃ substrate, depositing a NiOₓ layer on an opposite surface of the substrate, and depositing a second electrode on the NiOₓ layer to yield the device.

### CROSS-REFERENCE TO RELATED APPLICATION

This application claims the benefit of U.S. Patent Application No. 63/585,718 filed on Sep. 27, 2023, which is incorporated herein by reference in its entirety.

### STATEMENT OF GOVERNMENT SUPPORT

This invention was made with government support under 2302696 awarded by the National Science Foundation and under DE-SC0021230 awarded by the Department of Energy. The government has certain rights in the invention.

### TECHNICAL FIELD

This invention relates to the design of p-n junctions prepared with Ga₂O₃ and to methods of preparation thereof.

### BACKGROUND

Ultra-wide bandgap (UWBG) semiconductors, such as gallium oxide (β-Ga₂O₃), aluminum nitride, diamond, and boron nitride, can be advantageous for power electronics due to their large bandgaps and high critical field. These properties can result in higher operating voltages, larger currents, increased efficiencies, and smaller device footprint compared to devices based on traditional semiconductors such as silicon and wide bandgap semiconductors such as silicon carbide and gallium nitride.

### SUMMARY

This disclosure describes Ga₂O₃ heterojunction bipolar devices and methods of fabricating the devices.

In a first general aspect, fabricating a Ga₂O₃ heterojunction bipolar device includes depositing a first electrode on a first surface of a substrate, wherein first the surface of the substrate comprises β-Ga₂O₃ defining a (2̅01), (001), or (010) crystal plane, depositing a NiOₓ layer on a second surface of the substrate, depositing a second electrode on a surface of the NiOₓ layer to yield the device; and annealing the device.

Implementations of the first general aspect may include one or more of the following features.

Depositing the first electrode on the first surface of the substrate can be achieved by E-beam evaporation of an electrically conductive material on the first surface of the substrate. The first electrode and the substrate can be annealed. Some implementations include defining a pattern (e.g., a circular pattern) on the substrate (e.g., through a photolithographic process) before depositing the NiOₓ layer on the second surface of the substrate. Depositing the NiOₓ layer can include E-beam evaporation followed by a lift-off process. The device can be annealed (e.g., by heating the device to a temperature in a range between 250° C. and 450° C. or in a range between 300° C. and 400° C.).

In a second general aspect, a Ga₂O₃ heterojunction bipolar device includes a first electrode, a second electrode, a β-Ga₂O₃ substrate between the first electrode and the second electrode, and a NiOₓ layer in contact with (2̅01), (001), or (010) plane of the β-Ga₂O₃ substrate. A surface of the β-Ga₂O₃ substrate defines a (2̅01), (001), or (010) plane, and the interface between the NiOₓ layer and the β-Ga₂O₃ substrate is a p-n heterojunction.

Implementations of the second general aspect may include one or more of the following features.

The β-Ga₂O₃ substrate is doped (e.g., with tin). A concentration of the dopant is typically in a range of 1×10⁻¹⁸ cm⁻³ to 10×10⁻¹⁸ cm⁻³ (e.g., 5×10⁻¹⁸ cm⁻³). A thickness of the NiOₓ layer is in a range of 0.1 μm to 0.3 μm.

NiOₓ/β-Ga₂O₃ p-n heterojunctions fabricated on (2̅01), (001), and (010) β-Ga₂O₃ substrates show distinctly anisotropic electrical properties. All three devices exhibited excellent rectification ≥10⁹, and turn-on voltages >2.0 V. The (010) device showed very different turn-on voltage, specific on-resistance, and reverse recovery time compared with (2̅01) and (001) devices. Moreover, it is calculated that the interface trap state densities for (2̅01), (001), and (010) plane devices are 4.3×10¹⁰, 7.4×10¹⁰, and 1.6×10¹¹ eV⁻¹cm⁻², respectively. These differences in the NiOₓ/β-Ga₂O₃ heterojunctions are attributed to the different atomic configurations, the density of dangling bonds, and interface trap state densities.

The details of one or more embodiments of the subject matter of this disclosure are set forth in the accompanying drawings and the description. Other features, aspects, and advantages of the subject matter will become apparent from the description, the drawings, and the claims.

### BRIEF DESCRIPTION OF DRAWINGS

FIG. 1A shows monoclinic crystal structure of β-Ga₂O₃ with crystal planes of (2̅01), (001), and (010) labelled. FIG. 1B is a schematic of fabricated NiOₓ/β-Ga₂O₃ p-n heterojunctions.

FIGS. 2A and 2B show I-V characteristics of NiOₓ/β-Ga₂O₃ p-n heterojunctions on three crystallographic orientations in linear scale and semi-log scale, respectively.

FIGS. 3A and 3B show C-V measurements and 1/C²-V plots, respectively, of NiOₓ/β-Ga₂O₃ p-n heterojunctions for three crystallographic orientations. FIGS. 3C-3E show C-f characteristics with corresponding fitting curves for devices on (2̅01), (001), and (010) planes, respectively.

FIGS. 4A-4C show temperature dependent I-V curves for the devices on (2̅01), (001), and (010), respectively. Variation of turn-on voltage and ideality factor of corresponding I-V curves are shown in FIGS. 4D-4F.

FIG. 5A shows recovery of NiOₓ/β-Ga₂O₃ p-n heterojunctions on three crystallographic orientations. FIG. 5B shows temperature-dependent reverse recovery of p-n diodes on (2̅01) plane.

### DETAILED DESCRIPTION

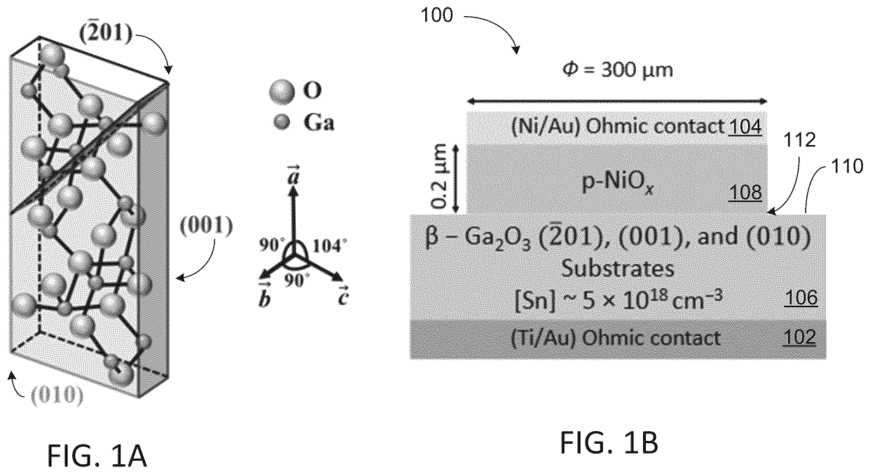

This disclosure describes Ga₂O₃ heterojunction bipolar devices and methods of fabricating the devices. FIG. 1A depicts the crystal structure of β-Ga₂O₃ and the corresponding planes used as substrates. FIG. 1B depicts Ga₂O₃ heterojunction bipolar device 100. Ga₂O₃ heterojunction bipolar device 100 has first electrode 102, second electrode 104, β-Ga₂O₃ substrate 106 between the first electrode and the second electrode, and NiOₓ layer 108 in contact with the (2̅01), (001), or (010) plane of β-Ga₂O₃ substrate 106. Surface 110 of β-Ga₂O₃ substrate 106 defines a (2̅01), (001), or (010) plane. Interface 112 between the NiOₓ layer and the β-Ga₂O₃ substrate is a p-n heterojunction. As depicted in FIG. 1B, components of Ga₂O₃ heterojunction bipolar device 100 have specific compositions and dimensions. However, other components in other embodiments may have different compositions, dimensions, or both.

First electrode 102 and second electrode 104 are composed of one or more metals. As depicted in FIG. 1B, first electrode 102 is composed of Ti/Al, and second electrode 104 is composed of Ni/Au. β-Ga₂O₃ substrate 106 can be doped (e.g., with tin). A concentration of the dopant is typically in a range of about 1×10⁻¹⁸ cm⁻³ to about 10×10⁻¹⁸ cm⁻³ (e.g., about 5×10⁻¹⁸ cm⁻³). A thickness of NiOₓ layer 108 is typically in a range of about 0.1 μm to about 0.3 μm (e.g., about 0.2 μm).

Fabricating Ga₂O₃ heterojunction bipolar device 100 includes depositing first electrode 102 on a first surface of substrate 106, depositing NiOₓ layer 108 on a second surface of substrate 106, depositing second electrode 104 on a surface of NiOₓ layer 108 to yield device 100, and annealing the device. The first the surface of substrate 106 defines a (2̅01), (001), or (010) crystal plane of β-Ga₂O₃. Depositing first electrode 102 on the first surface of substrate 106 can be achieved by E-beam evaporation of an electrically conductive material on the first surface of substrate 106. First electrode 102 and substrate 106 can be annealed. A pattern (e.g., a circular pattern) can be defined (e.g., with a photolithographic process) on substrate 106 before depositing NiOₓ layer 108 on the second surface of substrate 106. Depositing the NiOₓ layer can include E-beam evaporation followed by a lift-off process. Device 100 is annealed by heating to a temperature in a range between 250° C. and 450° C. (e.g., between 300° C. and 400° C.).

The low crystal symmetry of monoclinic β-Ga₂O₃ results in highly anisotropic material with direct impact on several key physical and electronic properties, such as dielectric constant, thermal conductivity, and electron mobility, which are different along different crystallographic directions. This anisotropy poses challenges for device fabrication and results in discrepancies in device performance. This disclosure describes a systematic comparative analysis of NiOₓ/β-Ga₂O₃ p-n heterojunctions with (2̅01), (001), and (010) substrate orientations. Results from temperature-dependent electrical measurements, reverse recovery characteristics, and capacitance-frequency (C-f) measurements provide better understanding of the anisotropic nature of NiOₓ/β-Ga₂O₃ p-n heterojunctions.

NiOₓ/β-Ga₂O₃ p-n heterojunctions fabricated on (2̅01), (001), and (010) substrates showed considerable differences in electrical properties in terms of turn-on voltages, ideality factor, on-resistance, and reverse recovery time. The (010) device exhibited the highest turn-on voltage of 2.50 V, the highest ideality factor of 2.13, the largest on-resistance of 6.50 mΩcm², and the lowest recovery time of 62 ns. The C-f measurements indicate an interface trap density of 4.3×10¹⁰, 7.4×10¹⁰, and 1.6×10¹¹ eV⁻¹ cm⁻² for (2̅01), (001), and (010) plane devices, respectively. All devices were fabricated simultaneously and exhibited excellent rectifying behaviors with high on/off ratio of ≥10⁹ and high-quality interfaces between NiOₓ and β-Ga₂O₃, as confirmed by HRTEM. These differences in device electrical properties are attributed to the different atomic configurations, the density of dangling bonds, and interface trap state densities.

Edge-defined film-fed grown (2̅01), (001), and (010) β-Ga₂O₃ substrates from Novel Crystal Technology were used. The substrates had similar n-type [Sn] doping concentrations of ˜5×10¹⁸ cm⁻³, similar thickness, and good crystalline quality, as verified by XRD measurements. To prepare the substrates, a standard cleaning procedure was implemented, which included cleaning with acetone, isopropyl alcohol, and deionized water, aided by sonication. The back contacts of Ti/Au (20/130 nm) were deposited using electron beam (E-beam) evaporation, followed by rapid thermal annealing at 500° C. in an N₂ environment. All back contacts showed very low contact resistance of <0.01 mΩcm². Standard photolithography was then performed to define circular patterns for the deposition of NiOₓ and the anode (diameter of 300 μm). 200 nm NiOₓ and the anode Ni/Au (20/130 nm) were deposited using E-beam evaporation, followed by a lift-off process. The anode, cathode, and NiOₓ layers were deposited simultaneously for all samples to avoid any inconsistencies in fabrication. All NiOₓ layers were highly doped with a similar hole density of >2×18 cm⁻³, and the Ohmic contacts to NiOₓ layers had a similar contact resistance of ˜0.3 mΩcm². After device fabrication, all samples were annealed at 350° C. in N₂ ambient for 1 minute. This annealing step was expected to improve the device performance by forming an Ohmic contact between the Ni/NiOₓ interface and reducing the number of interface states at the NiOₓ/β-Ga₂O₃ heterojunction.

Electrical characterization was conducted using a probe station equipped with a controllable thermal chuck, Keithley 4200-SCS parameter analyzer, and ultra-fast pulse measurement units. Cross-sectional transmission electron microscope (XTEM) images were taken for all samples. The TEM samples were prepared using a Thermo Fisher Helios 5UX Dualbeam system with final thinning in a Gatan precision ion-polishing system. The milling started with a Ga-focused ion beam at 30 keV, followed by thinning at 5 and 2 keV, and subsequent Ar-ion thinning at 2 and 1 keV. Devices with (2̅01), (001), and (010) β-Ga₂O₃ substrate normals were imaged along their respective [010], [100] and [001] zone axes. High-resolution TEM (HRTEM) images were taken using a Philips CM 200 operated at 200 kV and an image-corrected FEI Titan 80-300 operated at 300 kV. An XTEM image of the full diode structure consisting of the top electrode (Au, Ni), NiOₓ, and β-Ga₂O₃ substrate was obtained. HRTEM images of the NiOₓ/β-Ga₂O₃ interface for samples grown on (2̅01), (001) and (010) substrates were also obtained. The polycrystalline nature of NiOₓ layers was evident in HRTEM images, and abrupt NiOₓ/β-Ga₂O₃ interfaces were clearly visible.

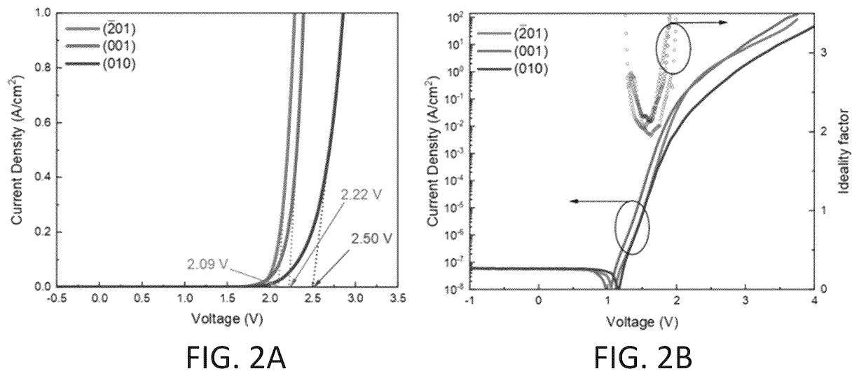

FIG. 2A shows I-V curves for the three NiOₓ/β-Ga₂O₃ p-n diodes, where the turn-on voltages were 2.09, 2.22, and 2.50 V for (2̅01), (001), and (010) substrates, respectively. Devices on (2̅01) and (001) planes had excellent rectification ratios of ˜10¹⁰ at ±3.75 V. However, (010) devices showed a smaller on/off ratio of about ˜10⁹ at ±3.75 V. Furthermore, devices on (2̅01) and (001) planes exhibited specific on-resistances of 2.92 and 1.55 mΩcm², while the (010) device showed a specific on-resistance of 6.50 mΩcm². Ideality factors were 1.95, 2.03, and 2.13 for (2̅01), (001), and (010) planes, respectively. These large ideality factors indicate that the current recombination in the heterojunction is dominant compared to diffusion currents.

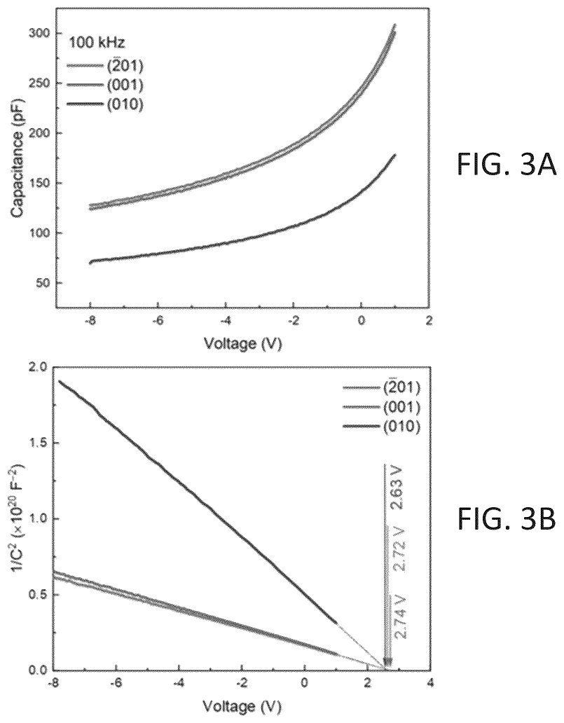

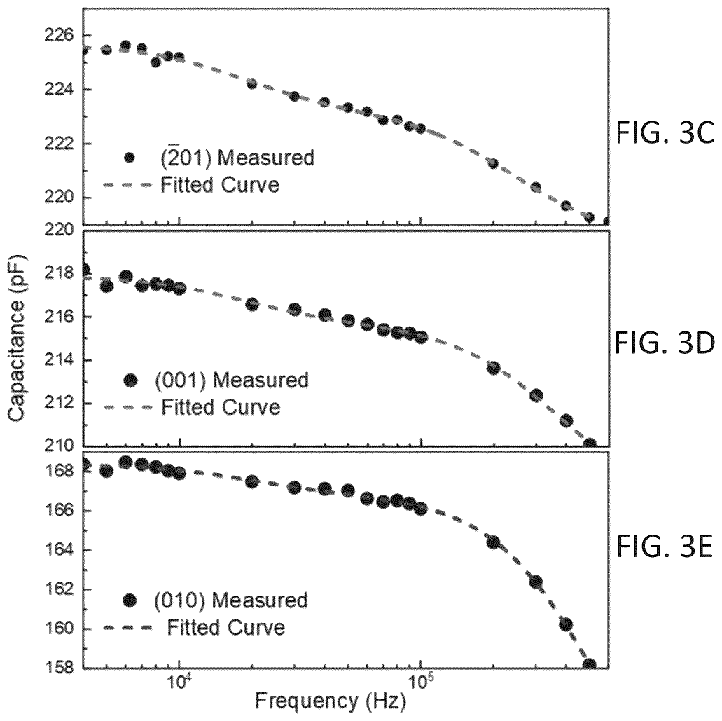

FIG. 3A shows C-V measurements performed at a frequency of 100 kHz. The devices showed built-in potentials of 2.72, 2.74, and 2.63 V on (2̅01), (001), and (010) devices, respectively as shown in FIG. 3B. The built-in voltages were comparable in all three devices since there is no current transport through the devices in C-V measurements. The built-in voltages determined by I-V and C V measurements showed some discrepancies. In general, C-V measurements are mainly affected by the doping concentration of NiOₓ and β-Ga₂O₃, as well as the charges from the interface states. However, they do not provide information about the current conduction through the interface. Conversely, extraction of built-in voltage through I-V measurements is influenced by the crystal anisotropy and interface states. The effective carrier concentration (N_{d}−Nₐ+Nₜ) calculated from the C-V measurements was 4.7×10¹⁸, 4.5×10¹⁸, 1.6×10¹⁸ cm⁻³ for (2̅01), (001), and (010) devices, respectively, where N_{d} is the ionized donor concentration, Nₐ is the ionized acceptor concentration, and Nₜ is the equivalent charge concentration of traps. Since the β-Ga₂O₃ and NiOₓ film in the three samples had similar carrier concentrations, the observed variation in the effective carrier concentrations is likely related to the different NiOₓ/β-Ga₂O₃ heterojunction interfaces caused by the crystal anisotropy, which is verified by C-f measurements.

FIGS. 3C-3E show C-f measurements for the devices on (2̅01), (001), and (010) substrates to evaluate the interface trap state density (Dᵢₜ). The C-f measurements are fitted using the equations below, assuming the interface states are distributed in two energy levels.

$$C = {C}_{sc} + \frac{{C}_{it - 1}}{{( 1 + 2 π f {τ}_{1} )}^{2}} + \frac{{C}_{it - 2}}{{( 1 + 2 π f {τ}_{2} )}^{2}} \qquad ( 1 )$$

$${D}_{it} = {C}_{it} / {q}^{2} A \qquad ( 2 )$$

where C_{sc} is the capacitance of the space charge region, and Cᵢₜ₋₁(Cᵢₜ₋₂) is the capacitance of the first state (second state) with their corresponding relaxation time τ₁ (τ₂). Cᵢₜ₋₁ represents an energy level that corresponds to interface states closer to the conduction band with smaller relaxation time, and Cᵢₜ₋₂ represents a deep energy level with a considerably larger relaxation time. A similar Cᵢₜ₋₂ of ˜2×10⁻¹² F was observed with a relaxation time of about ˜8 μs for all devices. This may represent deep-level states (e.g., vacancies) with relaxation time much larger than the interface states. However, Cᵢₜ₋₁ varied significantly for devices on different crystal orientations. The relaxation time for Cᵢₜ₋₁ was 0.64, 0.43 and 0.34 μs for (201), (001), and (010) devices, respectively. Cᵢₜ₋₁ changed with crystal orientation, while Cᵢₜ₋₂ remained relatively constant. It should be noted that the exact nature of the defect states in NiOₓ/β-Ga₂O₃ diodes is still unclear and demands further investigation. The extracted interface trap densities (Dᵢₜ₋₁) from Cᵢₜ₋₁ were 4.3×10¹⁰, 7.4×10¹⁰, and 1.6×10¹¹ eV⁻¹ cm⁻² for (2̅01), (001), and (010) devices, respectively. The interface states derived from Cᵢₜ₋₁ are much closer to the conduction band, and thus may play an important role in the device performance. Table 1 summarizes all the parameters extracted through C-f curve fitting.

TABLE 1
Interface state parameters extracted from C-f curve fitting.

| | | | | | D_{it - 1} | D_{it - 2} |
|---|---|---|---|---|---|---|
| Orientation | C_{it - 1} (F) | C_{it - 2} (F) | τ₁ (s) | τ₂ (s) | (eV⁻¹cm⁻²) | (eV⁻¹cm⁻²) |
| (2̅01) | 4.80 × 10⁻¹² | 2.50 × 10⁻¹² | 0.64 × 10⁻⁶ | 8.69 × 10⁻⁶ | 4.3 × 10¹⁰ | 2.2 × 10¹⁰ |
| (001) | 8.36 × 10⁻¹² | 2.27 × 10⁻¹² | 0.43 × 10⁻⁶ | 8.57 × 10⁻⁶ | 7.4 × 10¹⁰ | 2.0 × 10¹⁰ |
| (010) | 1.79 × 10⁻¹¹ | 1.62 × 10⁻¹² | 0.34 × 10⁻⁶ | 8.02 × 10⁻⁶ | 1.6 × 10¹¹ | 1.4 × 10¹⁰ |

The differences in electrical properties of NiOₓ/β-Ga₂O₃ p-n heterojunctions can be attributed to several factors. First, the difference in interface states may be significantly promoted by the density of dangling bonds. If the number of dangling bonds is high, then the adhesion of NiOₓ layer is promoted, exhibiting fewer interface states. Due to the higher dangling bond density in (2̅01) and (001) plane, it is easier to form better-quality NiOₓ/β-Ga₂O₃ heterojunction with high surface energy. This is analogous to the fact that forming Ohmic contacts on (2̅01) and (001) planes are easier than on (010) plane. Second, different doping concentrations can be induced in the heterojunction due to interface states. The interface states can have a big impact on net charge density. It is likely that there are lower compensating trap states in (2̅01) and (001) NiOₓ/β-Ga₂O₃ p-n heterojunctions as indicated by the C-f measurement, contributing larger net charge densities. This is further evidenced by the different gradients in the 1/C²-V plot. The observed differences are primarily influenced by the presence of interface states, considering three NiOₓ and β-Ga₂O₃ in the three samples had similar carrier concentrations. As discussed later, a difference in reverse recovery time (tᵣᵣ) of the devices was observed, indicating that carrier recombination on different planes is affected by the crystal anisotropy.

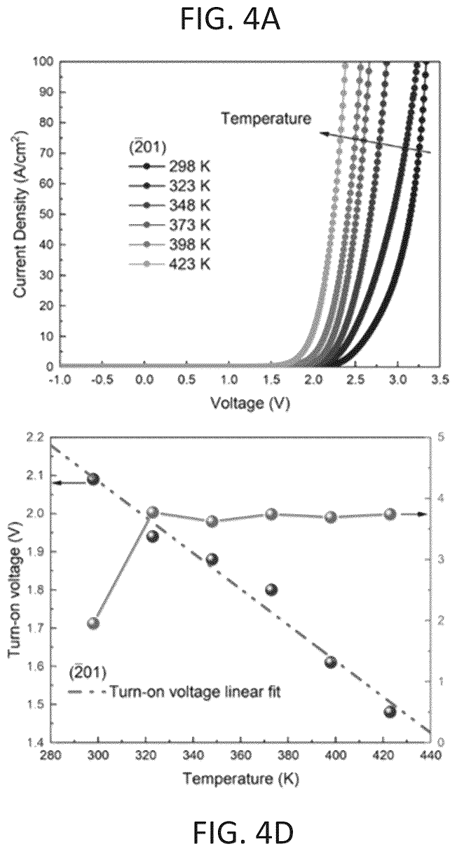

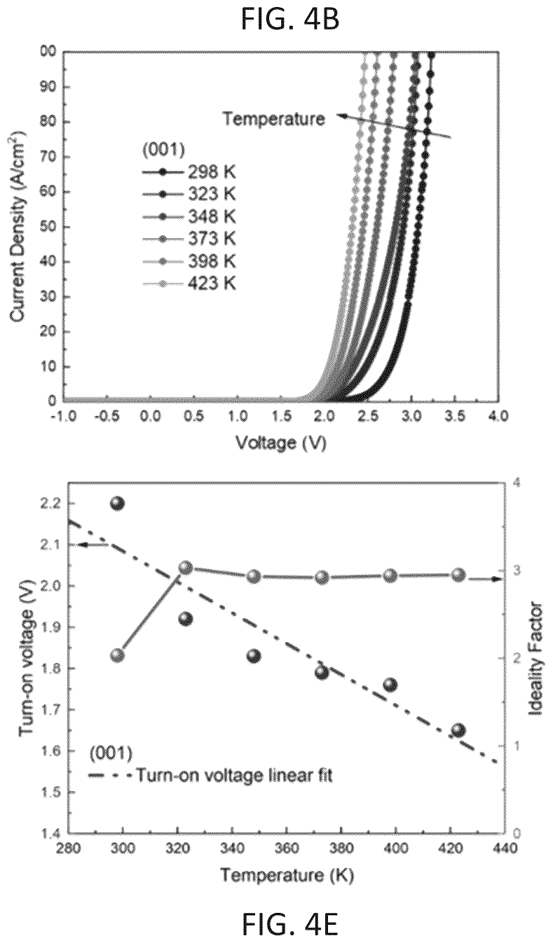

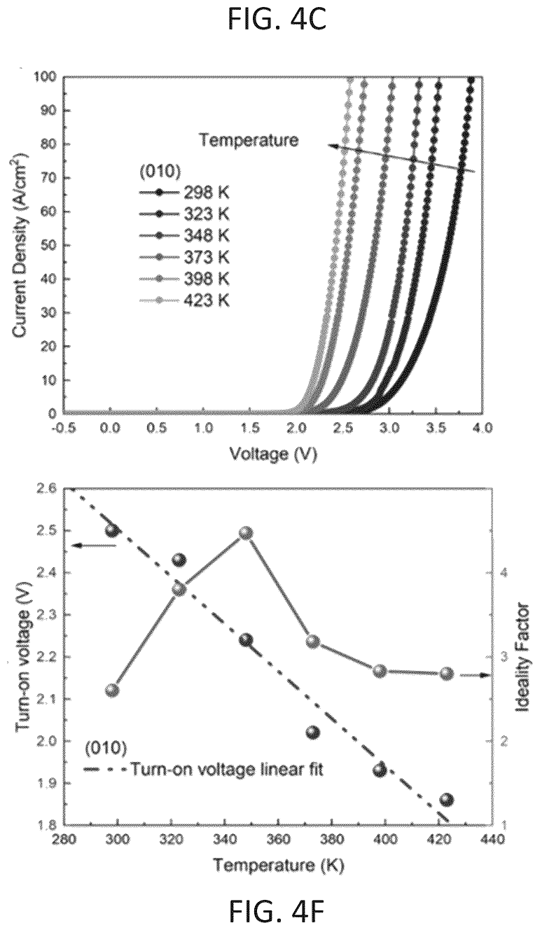

The temperature-dependent forward characteristics of three NiOₓ/β-Ga₂O₃ p-n diodes are shown in FIGS. 4A-4C. The observed temperature-dependent behavior was stable and reproducible, and the initial I-V curves were retained even after heating and cooling down, indicating excellent thermal stability of the heterojunction. The device ideality factor and turn-on voltage were extracted as a function of temperature, as shown in FIGS. 4D-4F. The turn-on voltage decreased linearly with the temperature, which can be attributed to the reduction of depletion width facilitating diffusion of holes. The ideality factor varied between 1.95-3.77, 2.03-2.95, and 2.13-4.47 in (2̅01), (001), and (010) devices, respectively. The ideality factor of (2̅01) and (001) devices remained almost constant under high temperatures. However, the ideality factor in (010) devices first increased and then decreased. This behavior can be attributed to the fact that there are 10 times more interface trap states in (010) heterojunction compared to (2̅01) and (001) heterojunctions. With increasing temperature, the carrier emission from interface traps is enhanced, affecting the ideality factor.

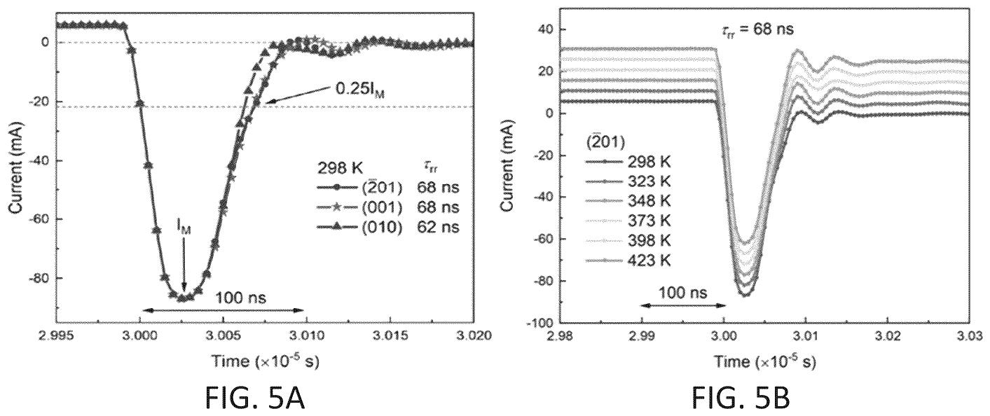

The tᵣᵣ of the diode is defined as the time it takes to reach 0.25I_{M} after switching off, where I_{M} is the maximum current during the reverse recovery period. The tᵣᵣ of the diodes is affected by several factors, including the doping concentration, the width of the depletion region, crystal anisotropy, and the applied voltage. In this work, all three samples were subject to voltages of ±5 V to observe the reverse recovery of the diode. The (2̅01) and (001) devices had a tᵣᵣ of 68 ns, while (010) devices took 62 ns to recover. The shorter reverse recovery time for (010) is likely due to larger interface defect densities that promote electron/hole recombination with a faster recovery time and mobility variation along different crystal orientations. All devices had a peak current of about 86 mA and showed temperature independence in reverse recovery time, as shown in FIG. 5B, where the y-axis is offset for clarity. This indicates that the junction capacitance and stored charges in the depletion region are independent of temperature. The forward current during the reverse recovery test was ˜6 mA. Additionally, the di/dt of three samples for the reverse recovery characteristics was 3.95 A/μs. The reverse recovery charge was 4.47, 4.54, and 4.26 nC for (2̅01), (001), and (010) devices, respectively. The different tᵣᵣ in different crystal orientations indicate carrier recombination is influenced by the interface states. Table 2 summarizes the device parameters of the three NiOₓ/β-Ga₂O₃ p-n heterojunctions, where Dᵢₜ of the devices is based on the dominant Dᵢₜ₋₁ values.

TABLE 2
Electrical properties of the NiOₓ/β-Ga₂O₃ p-n diode heterojunctions grown on (2̅
01), (001), and (010) substrates.

| | Vₒₙ(I − V) | V_{bi}(C − V) | Rₛₚ₋ₒₙ | on/off | | tᵣᵣ | Dᵢₜ |
|---|---|---|---|---|---|---|---|
| Orientation | (V) | (V) | (mΩcm²) | ratio | η | (ns) | (eV⁻¹cm⁻²) |
| (2̅01) | 2.09 | 2.74 | 2.92 | 10¹⁰ | 1.95 | 68 | 4.3 × 10¹⁰ |
| (001) | 2.22 | 2.72 | 1.55 | 10¹⁰ | 2.03 | 68 | 7.4 × 10¹⁰ |
| (010) | 2.50 | 2.63 | 6.50 | 10⁹ | 2.13 | 62 | 1.6 × 10¹¹ |

Although this disclosure contains many specific embodiment details, these should not be construed as limitations on the scope of the subject matter or on the scope of what may be claimed, but rather as descriptions of features that may be specific to particular embodiments. Certain features that are described in this disclosure in the context of separate embodiments can also be implemented, in combination, in a single embodiment. Conversely, various features that are described in the context of a single embodiment can also be implemented in multiple embodiments, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular embodiments of the subject matter have been described. Other embodiments, alterations, and permutations of the described embodiments are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results.

Accordingly, the previously described example embodiments do not define or constrain this disclosure. Other changes, substitutions, and alterations are also possible without departing from the spirit and scope of this disclosure.

What is claimed is:

1. A method of fabricating a Ga₂O₃ heterojunction bipolar device, the method comprising:
depositing a first electrode on a first surface of a substrate, wherein first the surface of the substrate comprises β-Ga₂O₃ defining a (2̅01), (001), or (010) crystal plane;
depositing a NiOₓ layer on a second surface of the substrate; and
depositing a second electrode on a surface of the NiOₓ layer to yield the device.

2. The method of claim 1, wherein depositing the first electrode on the first surface of the substrate comprises E-beam evaporation of an electrically conductive material on the first surface of the substrate.

3. The method of claim 2, further comprising annealing the first electrode and the substrate.

4. The method of claim 1, further comprising defining a pattern on the substrate before depositing the NiOₓ layer on the second surface of the substrate.

5. The method of claim 4, wherein defining the pattern comprises a photolithographic process.

6. The method of claim 4, wherein the pattern is a circular pattern.

7. The method of claim 1, wherein depositing the NiOₓ layer comprises E-beam evaporation followed by a lift-off process.

8. The method of claim 1, further comprising annealing the device.

9. The method of claim 8, wherein the annealing comprises heating the device to a temperature in a range between 250° C. and 450° C.

10. The method of claim 9, wherein the temperature is in a range between 300° C. and 400° C.

11. A Ga₂O₃ heterojunction bipolar device comprising:
a first electrode;
a second electrode;
a β-Ga₂O₃ substrate between the first electrode and the second electrode, wherein a surface of the β-Ga₂O₃ substrate defines a (2̅01), (001), or (010) plane; and
a NiOₓ layer in contact with (2̅01), (001), or (010) plane of the β-Ga₂O₃ substrate,
wherein the interface between the NiOₓ layer and the β-Ga₂O₃ substrate is a p-n heterojunction.

12. The device of claim 11, wherein the β-Ga₂O₃ substrate is doped.

13. The device of claim 12, wherein the β-Ga₂O₃ substrate is doped with tin.

14. The device of claim 13, wherein a concentration of the tin in the β-Ga₂O₃ substrate is in a range of 1×10⁻¹⁸ cm⁻³ to 10×10⁻¹⁸ cm⁻³.

15. The device of claim 11, wherein a thickness of the NiOₓ layer is in a range of 0.1 μm to 0.3 μm.
